(19) United States
(12) Patent Application Publication
(10) Pub. No.: US 2009/0017586 A1
(43) Pub. Date: Jan. 15, 2009

(54) CHANNEL STRESS MODIFICATION BY CAPPED METAL-SEMICONDUCTOR LAYER VOLUME CHANGE

(75) Inventors: Sunfei Fang, LaGrangeville, NY (US); Zhijiong Luo, Carmel, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/774,841

(22) Filed: Jul. 9, 2007

(51) Int. Cl. H01L 21/8238

(52) U.S. Cl. 438/199; 257/E21.632

(57) ABSTRACT

A method for fabricating a field effect device, such as a field effect transistor, uses a first metal-semiconductor layer, such as a first metal-silicide layer, adjacent a channel in the field effect device. The first metal-semiconductor layer has a first volume. The first metal-semiconductor layer is capped with a capping layer and processed to form a second metal-semiconductor layer that has a second volume different than the first volume. Due to the presence of the capping layer, the difference in volume between the second volume and the first volume introduces a stress into the channel of the field effect device.

### BACKGROUND

1. Field of the Invention

The invention relates generally to field effect devices. More particularly, the invention relates to channel stress within field effect devices.

2. Description of the Related Art

Semiconductor circuits include semiconductor devices such as resistors, transistors, capacitors and diodes. Common within semiconductor circuits are field effect devices and related structures, such as in particular field effect transistors. Field effect transistors have been effectively scaled in dimension for several decades to provide continuing advances in functionality and performance of semiconductor circuits.

As field effect transistor structure and device dimensions have continuously decreased, more recent advances in field effect transistor performance have centered upon the use of different crystallographic orientation semiconductor substrates, as well as different channel stress types and different channel stress directions, when fabricating field effect transistors. Such different crystallographic orientation semiconductor substrates, different channel stress types and different channel stress directions often influence a charge carrier mobility within a field effect transistor. For example, a compressive channel stress in a vertical direction is useful for enhancing an electron charge carrier mobility within an n polarity type field effect transistor (i.e., an n FET).

Channel stress within field effect devices is likely to be of considerable continued importance as field effect device dimensions continue to be scaled to increasingly smaller dimensions. Thus, desirable are novel methods and materials for introducing channel stress within field effect devices, such as field effect transistors.

### SUMMARY OF THE INVENTION

The invention provides a method for introducing a mechanical stress within a channel of a field effect device, such as a field effect transistor. The invention effects the foregoing result by first forming adjacent the channel a first metal-semiconductor layer comprising a first metal-semiconductor material having a first volume. The first metal-semiconductor layer is capped with a capping layer and then processed and transformed into a second metal-semiconductor layer comprising a second metal-semiconductor material having a second volume different than the first volume. The difference in volume between the second volume and the first volume also considers consumption of any adjoining semiconductor material when transforming the first metal-semiconductor layer into the second metal-semiconductor layer. Due to the presence of the capping layer, the difference in volume between the second volume and the first volume introduces a mechanical stress into the channel of the field effect device.

Within the invention, each of the first volume and the second volume may be regarded as a “specific volume” (i.e., a volume per unit mass, which in turn is generally an inverse of a density). Thus, an increase in a volume change between a first volume and a second volume corresponds with a less dense metal-semiconductor material for the second metal-semiconductor layer.

A particular method in accordance with the invention includes forming adjacent a channel within a field effect device a first metal-semiconductor layer having a first volume. This particular method also includes capping the first metal-semiconductor layer with a capping layer to provide a capped first metal-semiconductor layer. This particular method also includes processing the capped first metal-semiconductor layer to transform the first metal-semiconductor layer to a second metal-semiconductor layer having a second volume different than the first volume. A difference between the first volume and the second volume introduces a stress into the channel.

Another particular method in accordance with the invention includes forming a gate electrode over a channel region that separates a plurality of source/drain regions within a semiconductor substrate. This other method includes forming a first metal-semiconductor layer having a first volume upon the gate electrode. This other method also includes capping the first metal-semiconductor layer. This other method also includes processing the capped first metal-semiconductor layer to form a second metal-semiconductor layer that has a second volume different than the first volume. The difference in volume between the second volume and the first volume introduces a stress into the channel region.

Yet another particular method in accordance with the invention includes forming a gate electrode over a channel region that separates a plurality of source/drain regions within a semiconductor substrate. This yet another method also includes forming a first metal-semiconductor layer having a first volume upon the source/drain regions. This yet another method also includes capping the first metal-semiconductor layer. This yet another method also includes processing the capped first metal-semiconductor layer to form a second metal-semiconductor layer that has a second volume different than the first volume. The difference in volume between the second volume and the first volume introduces a stress into the channel region.

### BRIEF DESCRIPTION OF THE DRAWINGS

The objects, features and advantages of the invention are understood within the context of the Description of the Preferred Embodiment, as set forth below. The Description of the Preferred Embodiment is understood within the context of the accompanying drawings, which form a material part of this disclosure, wherein:

FIG. 1 to FIG. 7 show a series of schematic cross-sectional diagrams illustrating the results of progressive stages in fabricating a semiconductor structure in accordance with a particular embodiment of the invention.

FIG. 8 to FIG. 11 show a series of schematic cross-sectional diagrams illustrating the results of progressive stages in fabricating a semiconductor structure in accordance with another particular embodiment of the invention.

### DESCRIPTION OF THE PREFERRED EMBODIMENT

The invention, which includes a method for introducing a mechanical stress into a channel within a field effect device (and in particular a field effect transistor), is understood within the context of the description that follows. The description that follows is understood within the context of the drawings described above. Since the drawings are intended for illustrative purposes, the drawings are not necessarily drawn to scale.

FIG. 1 to FIG. 7 show a series of schematic cross-sectional diagrams illustrating the results of progressive stages in fabricating a semiconductor structure in accordance with a particular embodiment of the invention. This particular embodiment of the invention comprises a first embodiment of the invention. The semiconductor structure fabricated in accordance with this particular first embodiment is a CMOS semiconductor structure. FIG. 1 shows a schematic cross-sectional diagram of the semiconductor structure at an early stage in the fabrication thereof in accordance with this embodiment.

FIG. 1 shows a semiconductor substrate 10 having a plurality of active regions that are separated by a plurality of isolation regions 12. Particular separated active regions within the plurality of active regions are intended for fabrication of an n FET (i.e., left hand active region) and a p FET (i.e., right hand active region).

The semiconductor substrate 10 may comprise any of several semiconductor materials. Non-limiting examples include silicon, germanium, silicon-germanium alloy, silicon-carbon alloy, silicon-germanium-carbon alloy and compound (i.e., III-V and II-VI) semiconductor materials. Non-limiting examples of compound semiconductor materials include gallium arsenide, indium arsenide and indium phosphide semiconductor materials. Typically, the semiconductor substrate 10 has a generally conventional thickness.

While FIG. 1 illustrates the instant embodiment within the context of the semiconductor substrate 10 as a bulk semiconductor substrate, this particular embodiment is not necessarily so limited. Rather, this embodiment also contemplates the use of a semiconductor-on-insulator substrate for the semiconductor substrate 10. A semiconductor-on-insulator substrate includes a buried dielectric layer that separates a base semiconductor substrate from a surface semiconductor layer within the semiconductor-on-insulator substrate. The base semiconductor substrate and the surface semiconductor layer may comprise the same or different semiconductor materials with respect to chemical composition, crystallographic orientation, dopant polarity and dopant concentration.

The embodiment also contemplates the use of a hybrid orientation substrate as the semiconductor substrate 10. A hybrid orientation substrate includes multiple semiconductor regions of different crystallographic orientations.

Semiconductor-on-insulator substrates and hybrid orientation substrates may be fabricated using any of several methods. Non-limiting examples include lamination methods, layer transfer methods and separation by implantation of oxygen (SIMOX) methods.

The isolation regions 12 may comprise any of several isolation materials that will typically comprise dielectric isolation materials. Typically, the isolation regions 12 comprise a dielectric isolation material selected from the group including but not limited to silicon oxide, silicon nitride and silicon oxynitride dielectric isolation materials. Other dielectric isolation materials are not excluded. Typically, the isolation regions 12 comprise a silicon oxide or a silicon nitride dielectric material, or a composite or a laminate thereof.

FIG. 1 also shows (in cross-section) an n FET T1 and a p FET T2 that include in-part: (1) a plurality of gate dielectrics 14 located upon corresponding active regions of the semiconductor substrate 10; (2) a plurality of gate electrodes 16 located upon the plurality of gate dielectrics 14; and (3) a plurality of capping layers 18 located upon the plurality of gate electrodes 16.

Each of the foregoing layers 14, 16 and 18 may comprise materials and have dimensions that are conventional in the semiconductor fabrication art. Each of the foregoing layers 14, 16 and 18 may also be formed using methods that are conventional in the semiconductor fabrication art.

The gate dielectrics 14 may comprise conventional dielectric materials such as oxides, nitrides and oxynitrides of silicon that have a dielectric constant from about 4 (i.e., typically a silicon oxide) to about 8 (i.e., typically a silicon nitride), measured in vacuum. Alternatively, the gate dielectrics 14 may comprise generally higher dielectric constant dielectric materials having a dielectric constant from about 8 to at least about 100. Such higher dielectric constant dielectric materials may include, but are not limited to hafnium oxides, hafnium silicates, zirconium oxides, lanthanum oxides, titanium oxides, barium-strontium-titantates (BSTs) and lead-zirconate-titanates (PZTs). The gate dielectrics 14 may be formed using any of several methods that are appropriate to their materials of composition. Non-limiting examples include thermal or plasma oxidation or nitridation methods, chemical vapor deposition methods (including atomic layer deposition methods) and physical vapor deposition methods. Typically, the gate dielectrics 14 comprise a thermal silicon oxide dielectric material that has a generally conventional thickness that may be in a range from about 10 to about 100 angstroms.

Within field effect transistors in general, gate electrodes (i.e., such as the gate electrodes 16) may comprise materials including but not limited to certain metals, metal alloys, metal nitrides and metal silicides, as well as laminates thereof and composites thereof. Such gate electrodes may also comprise doped polysilicon and polysilicon-germanium alloy materials (i.e., having a dopant concentration from about 1e18 to about 1e22 dopant atoms per cubic centimeter) and polycide materials (doped polysilicon/metal silicide stack materials). Similarly, the foregoing materials may also be formed using any of several methods. Non-limiting examples include salicide methods, chemical vapor deposition methods and physical vapor deposition methods, such as, but not limited to evaporative methods and sputtering methods. Within the instant embodiment, and for reasons that will become clearer within the context of further disclosure below, the gate electrodes 16 comprises a doped semiconductor material such as but not limited to a doped polysilicon material, a doped polygermanium material or a doped polysilicon-germanium alloy material, that has a thickness from about 200 to about 2000 angstroms.

The capping layer 18 comprises a capping material that in turn typically comprises a hard mask material. Dielectric hard mask materials are most common but by no means limit the instant embodiment or the invention. Non-limiting examples of hard mask materials include oxides, nitrides and oxynitrides of silicon. Oxides, nitrides and oxynitrides of other elements are not excluded. The capping material 18 may be formed using any of several methods that are conventional in the semiconductor fabrication art. Non-limiting examples include chemical vapor deposition methods and physical vapor deposition methods. Typically, the capping layer 18 comprises a silicon nitride capping material that has a thickness from about 20 to about 500 angstroms.

FIG. 1 also shows a plurality of first spacers 20 located adjacent and adjoining opposite sidewalls (i.e., a plurality of spacers in cross-sectional view but a single spacer in plan-view) of the gate dielectrics 14, the gate electrodes 16 and capping layers 18. FIG. 1 also shows a plurality of second spacers 22 located upon the sidewalls of the plurality of first spacers. FIG. 1 finally shows a plurality of source/drain regions 24 located within the active regions of the semiconductor substrate 10 and separated at least in part by the gate electrodes 16.

The first spacers 20 and the second spacers 22 each typically comprise a dielectric spacer material. Similarly with other dielectric structures within the instant embodiment, candidate dielectric spacer materials again include oxides, nitrides and oxynitrides of silicon. Also again, oxides, nitrides and oxynitrides of other elements are not excluded. The first spacers 20 are formed in a first instance using a conformal blanket layer deposition method and the second spacers 22 are also formed using a blanket conformal layer deposition method. Both the first spacers 20 and the second spacers 22 are formed from their blanket conformal layers while using an anisotropic etching plasma for etching purposes. Typically, the first spacers 20 comprise a different dielectric material than the second spacers 22, but such a difference is not a requirement of the embodiment. Typically, the first spacers 20 comprise a silicon oxide material when the second spacers 22 comprise a silicon nitride material. Alternative materials selections for the first spacers 20 and the second spacers 22 are also within the context of the instant embodiment.

The source/drain regions 24 comprise a dopant appropriate to the polarity of the n FET T1 and p FET T2 desired to be fabricated. As is understood by a person skilled in the art, the source/drain regions 24 are formed using a two-step ion implantation method. A first step within the two-step ion implantation method uses at least the gate electrodes 16 as a mask to form extension regions into the active regions of the semiconductor substrate 10. A second step within the two-step ion implantation method uses the gate electrodes 16, the first spacers 20 and the second spacers 22 as a mask to form larger contact region portions of the source/drain regions 24 that incorporate the extension region portions of the source/drain regions 24.

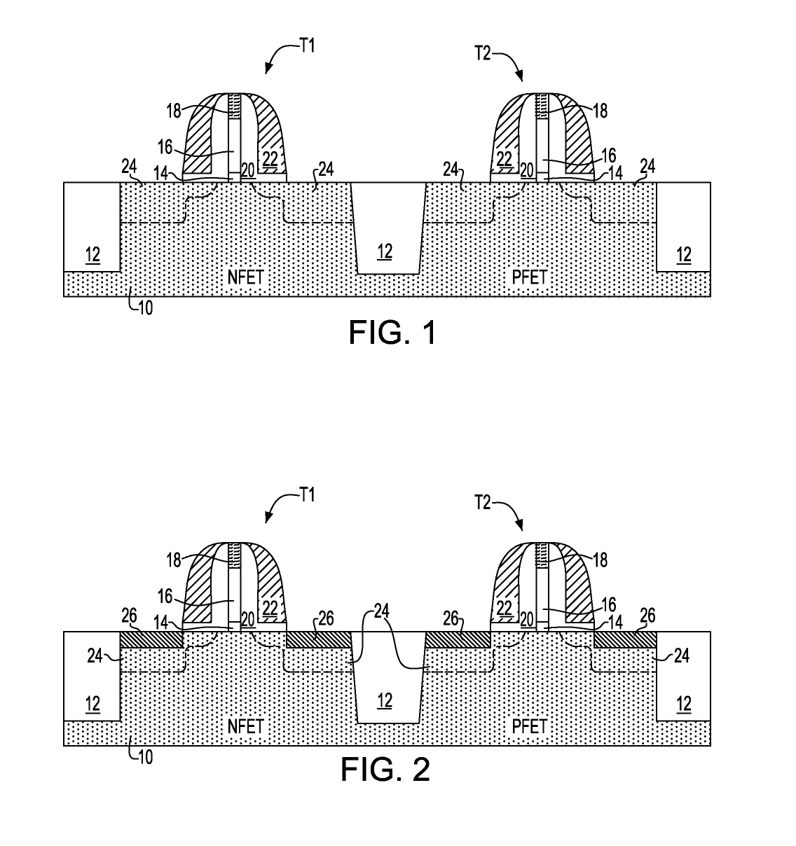

FIG. 2 shows source/drain metal-semiconductor layers 26 located upon the source/drain regions 24 within each of the transistors T1 and T2. Within the instant embodiment, the source/drain metal-semiconductor layers 26 may comprise generally conventional metal-semiconductor forming metals. Non-limiting examples of candidate metal-semiconductor forming metals include nickel, cobalt, titanium, tungsten, erbium, ytterbium, platinum and vanadium metal-semiconductor e forming metals. Nickel and cobalt metal-semiconductor forming metals are particularly common. Others of the above enumerated metal-semiconductor forming metals are less common. Typically, the source/drain metal-semiconductor layers 26 are formed using a salicide method. The salicide method includes: (1) forming a blanket metal-semiconductor forming metal layer upon the semiconductor structure of FIG. 1; (2) thermally annealing the blanket metal-semiconductor forming metal layer with semiconductor surfaces which it contacts (i.e., as listed above within the context of the description of the semiconductor substrate 10) to selectively form the source/drain metal-semiconductor layers 26 while leaving unreacted metal-semiconductor forming metal layers on, for example, the spacers 22 and the isolation regions 12; and (3) selectively stripping unreacted portions of the metal-semiconductor forming metal layers from, for example, the spacers 22 and the isolation regions 12. Typically, the source/drain metal-semiconductor layers 26 comprise a nickel silicide material or a cobalt silicide material that has a thickness from about 50 to about 500 angstroms.

Metal-semiconductor layer formation often uses an additional thermal anneal after removal of an unreacted metal-semiconductor forming metal in accordance with disclosure above. Such an additional thermal anneal may provide for improved junction leakage properties and improved semiconductor layer to metal-semiconductor layer properties within a particular semiconductor structure. Improvements in other physical, mechanical or electrical properties may also be realized. Such an additional thermal anneal may also transform an initially formed metal-semiconductor layer (i.e., typically metal silicide layer), into a preferred lower resistance phase (i.e. the source/drain metal-semiconductor layers 26 may comprise a biphasic metal-semiconductor material in accordance with further description below). Such a biphasic metal-semiconductor material is not precluded within the context of the metal-semiconductor forming metals disclosed above. As will be illustrated within the context of such further description below, such a biphasic metal-semiconductor material may undergo a thermal annealing induced phase change that provides a volume change of the source/drain metal-semiconductor layers 26.

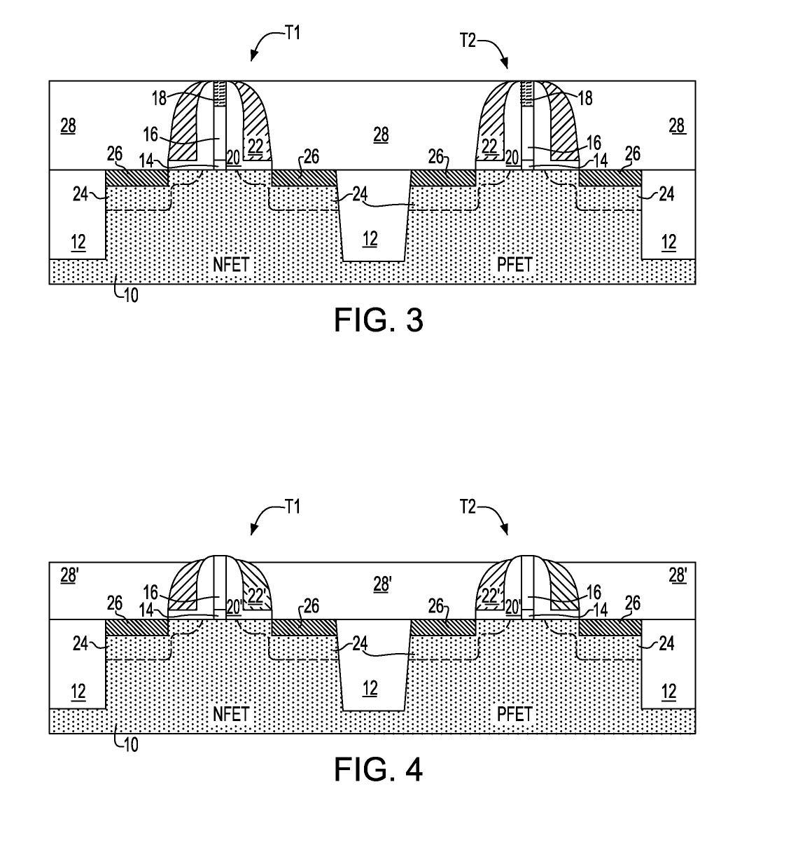

FIG. 3 shows the results of forming and planarizing an inter-level dielectric (ILD) layer 28 upon the semiconductor structure of FIG. 2. The inter-level dielectric layer 28 may be formed and planarized upon the semiconductor structure of FIG. 2 to provide the semiconductor structure of FIG. 3 while using methods and materials that are otherwise generally conventional in the semiconductor fabrication art. The inter-level dielectric layer 28 may comprise materials analogous, equivalent or identical to the materials from which is comprised the isolation regions 12. Alternatively, the inter-level dielectric layer 28 may comprise generally lower dielectric constant dielectric materials such as but not limited to spin-on-glass materials, spin-on-polymer materials, carbon doped silicon oxide materials, fluorine doped silicon oxide materials, nanoporous materials and microporous materials. Typically, the inter-level dielectric layer 28 is formed as a blanket layer and planarized using a chemical mechanical polish (CMP) planarizing method.

FIG. 4 shows the results of etching back the inter-level dielectric layer 28, the first spacers 20 and the second spacers 22, while simultaneously stripping the capping layers 18 from the semiconductor structure whose schematic cross-sectional diagram of FIG. 3. The inter-level dielectric layer 28, the first spacers 20 and the second spacers 22 may be etched back to form the inter-level dielectric layer 28′, the first spacers 20′ and the second spacers 22′ while stripping the capping layers 18, while using etch methods that are otherwise generally conventional in the semiconductor fabrication art. Typically, such etch methods will include plasma etch methods that will generally include a fluorine containing etchant gas composition of limited specificity. As is illustrated within the schematic cross-sectional diagram of FIG. 4, as a result of the foregoing etching the gate electrodes 16 are exposed.

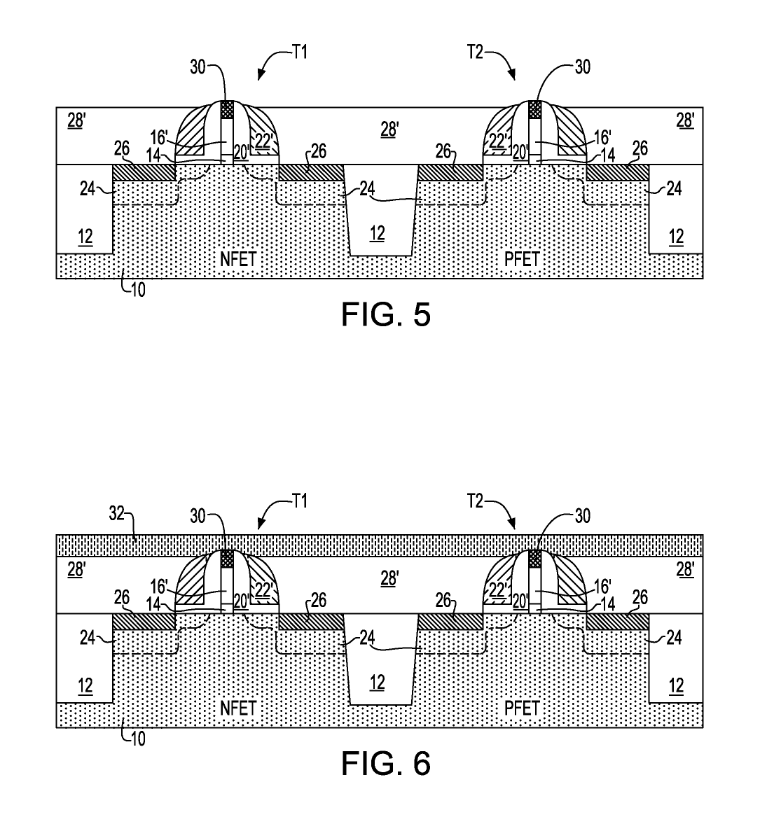

FIG. 5 shows a plurality of gate metal-semiconductor layers 30 located upon a plurality of gate electrodes 16′. The plurality of gate metal-semiconductor layers 30 in particular is formed of a metal-semiconductor forming metal that is capable of forming biphasic metal-semiconductor layers. The biphasic metal-semiconductor layers have a first phase that has a first volume and a second phase that has a second volume different (and typically but not necessarily greater) than the first volume. The second volume may also take into consideration consumption of additional semiconductor material from which is comprised the gate electrodes 16. A particularly desirable biphasic metal-semiconductor forming metal that may be used within the context of the instant embodiment is osmium, which forms a first osmium rich osmium-silicide-semiconductor phase (OsSi) and a second semiconductor rich osmium-silicide-semiconductor phase (OsSi2). The first osmium rich phase (OsSi) has a smaller volume than the second semiconductor rich phase (OsSi2). The first osmium rich phase may be formed using a first thermal annealing at a temperature of about 200 to about 400 degrees centigrade. The second silicon semiconductor rich phase may be formed from the first osmium rich phase using a second thermal annealing at a temperature from about 400 to about 600 degrees centigrade.

A biphasic metal-semiconductor forming metal that exhibits a volume contraction upon sequential thermal annealing is a nickel metal-silicide-semiconductor forming metal where a first nickel rich phase (Ni2Si) has a larger volume than a second semiconductor rich phase (NiSi), when considering the Si volume consumed during the 2nd phase transformation.

Additional information regarding metal silicides may be found in Maex et al., ed., “Properties of Metal Silicides,” Emis DataReview Series No. 14, Inspec, 1995, (see, e.g., pg. 20 for nickel silicides and osmium silicides). Determining operative biphasic metal-semiconductor forming metals in accordance with the invention is not regarded as requiring undue experimentation insofar as such a determination in a first instance requires merely a determination of multiphasic behavior of a particular metal-semiconductor forming metal, along with particular densities or specific volumes of particular phases within the multiphasic behavior.

FIG. 6 shows a capping layer 32 located upon the semiconductor structure of FIG. 5. The capping layer 32 comprises a capping material that is preferably a dielectric material. Typically, the capping layer 32 comprises a silicon nitride material, a silicon oxynitride, or silicide dioxide material that may be formed using generally conventional methods that are disclosed above for forming other dielectric structures within the semiconductor structure of the instant embodiment. Typically, the capping layer 32 has a thickness from about 200 to about 10000 angstroms to provide the capping layer 32 with structural rigidity.

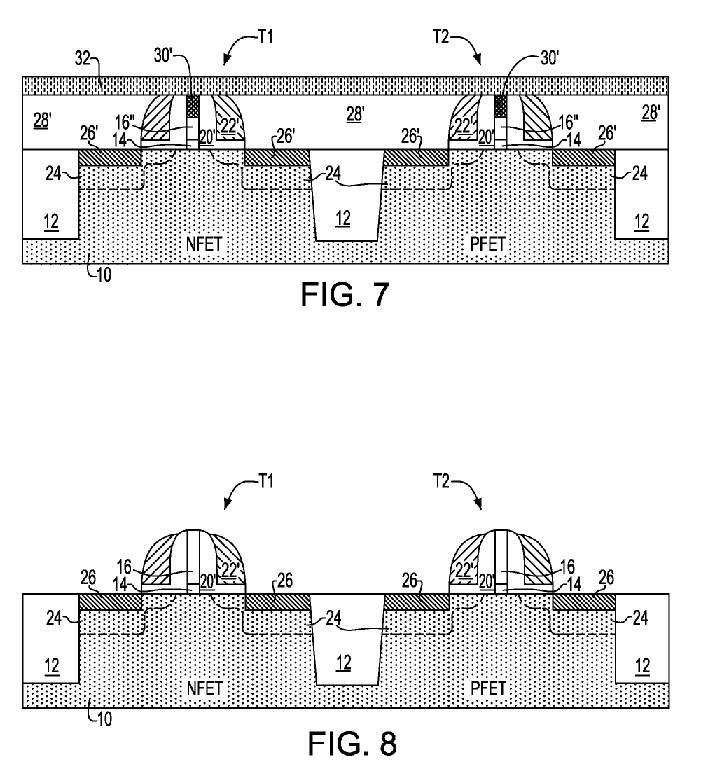

FIG. 7 shows the results of further processing of the semiconductor structure whose schematic cross-sectional diagram is illustrated in FIG. 6. More particularly, FIG. 7 shows the results of thermally annealing the semiconductor structure whose schematic cross-sectional diagram is illustrated in FIG. 6. Incident to thermal annealing of the semiconductor structure whose schematic cross-sectional diagram is illustrated in FIG. 6, FIG. 7 illustrates a plurality of gate metal-semiconductor layers 30′ that provide a volumetric change in comparison with the plurality of gate metal-semiconductor layers 30, even when taking into consideration consumption of the gate electrodes 16′ to from the gate electrodes 16″. The volumetric change is typically a volumetric expansion, although, as noted above within the context of a nickel metal-semiconductor forming metal, a volumetric contraction is not precluded within the context of the embodiment. Due to the volumetric change of the gate metal-semiconductor layers 30′ in comparison with the gate metal-semiconductor layers 30, and insofar as the volumetric change is contained by the capping layer 32, a mechanical stress is transmitted through the gate electrodes 16″ and the gate dielectrics 14 and transferred (i.e., introduced) into the channel regions of the n FET T1 and the p FET T2 as a compressive channel stress in a vertical channel direction. Such a compressive channel stress in a vertical channel direction is particularly desirable within an n FET since such a compressive channel stress in a vertical channel direction provides for an enhanced electron charge carrier mobility enhancement within an n FET.

As is disclosed above, the embodiment also contemplates that the source/drain metal-semiconductor layers 26 may also be biphasic or otherwise susceptible to a volumetric expansion or a volumetric contraction to provide the source/drain metal-semiconductor layers 26′ that are illustrated in FIG. 7. Thus, while a change in volume with respect to the gate metal-semiconductor layers 30/30′ may provide either a vertical tensile stress or a vertical compressive stress within the channel regions of the n FET T1 and the p FET T2, a change in volume with respect to the source/drain metal-semiconductor layers 26/26′ may provide either a lateral tensile stress or a lateral compressive stress within the channel regions of the n FET T1 and the p FET T2.

FIG. 7 shows a schematic cross-sectional diagram of a semiconductor structure (i.e., a CMOS semiconductor structure) in accordance with a particular embodiment of the invention that comprises a first embodiment of the invention. The semiconductor structure in particular includes a gate metal-semiconductor layer 30′ (i.e., a second gate metal-semiconductor layer) that has a second volume and that results from further processing (i.e., thermal annealing) of a metal-semiconductor layer 30 (i.e., a first metal-semiconductor layer) that has a first volume different than the second volume. The volumetric change between the second volume and the first volume (which is generally but not necessarily a positive volume change) introduces a stress (which is generally but not exclusively a compressive stress) within a channel region of the n FET T1 and the p FET T2. The compressive stress within the n FET T1 channel is particularly desirable within the semiconductor structure of FIG. 7 insofar as such a compressive channel stress provides for enhanced electron charge carrier mobility within the n FET T1.

FIG. 8 to FIG. 11 show a series of schematic cross-sectional diagrams illustrating the results of progressive stages in fabricating a semiconductor structure (i.e., also a CMOS semiconductor structure) in accordance with another embodiment of the invention. This other embodiment of the invention comprises a second embodiment of the invention. FIG. 8 shows a schematic cross-sectional diagram of the semiconductor structure at an early stage in fabrication thereof in accordance with this other embodiment of the invention.

FIG. 8 follows analogously from FIG. 4 and may in particular directly result from further processing of the semiconductor structure whose schematic cross-sectional diagram is illustrated in FIG. 4 by removing the inter-level dielectric layer 28′. Alternatively, the semiconductor structure whose schematic cross-sectional diagram is illustrated in FIG. 8 may result from a further anisotropic etching of the semiconductor structure whose schematic cross-sectional diagram is illustrated in FIG. 2 (i.e., absent the inter-level dielectric layer 28 formed and planarized thereupon). Within the context of either of the foregoing processing sequences, like structures within the schematic cross-sectional diagrams of FIG. 4 and FIG. 8 are numbered identically.

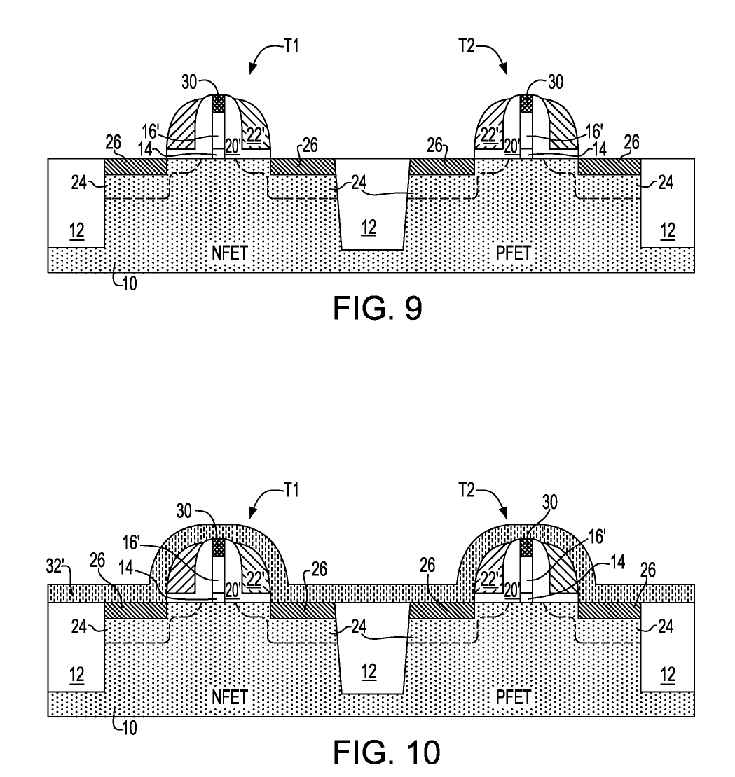

FIG. 9 shows the gate metal-semiconductor layers 30 that are also illustrated in FIG. 5. The gate-metal-semiconductor layers 30 may be formed using a salicide method at a sufficiently low temperature so that the source/drain metal-semiconductor layers 26 effectively block formation thereupon of additional metal-semiconductor materials.

FIG. 10 shows a capping layer 32′ located upon the semiconductor structure of FIG. 9. The capping layer 32′ that is illustrated in FIG. 10 is otherwise generally analogous, equivalent or identical to the capping layer 32 that is illustrated in FIG. 6, but for a difference in topographies of the capping layer 32 that is illustrated in FIG. 6 in comparison with the capping layer 32′ that is illustrated in FIG. 10.

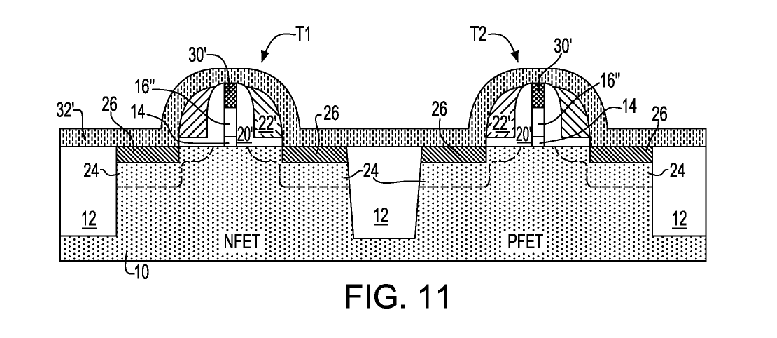

FIG. 11 shows the results of further processing of the semiconductor structure whose schematic cross-sectional diagram is illustrated in FIG. 10. FIG. 11 shows the results of thermally annealing the semiconductor structure of FIG. 10 to form a plurality of gate metal-semiconductor layers 30′ from the metal-semiconductor layers 30. The processing that is illustrated in FIG. 11 in comparison with FIG. 10 is otherwise analogous, equivalent or identical to the processing that is illustrated in FIG. 7 in comparison with FIG. 6. Similarly with FIG. 7, the gate metal-semiconductor layers 30′ differ in volume (i.e., typically but not necessarily an increase in volume) in comparison with the gate metal-semiconductor layers 30 that are illustrated in FIG. 10. As a result of this volumetric difference, in conjunction with a capping by the capping layer 32′, a vertical mechanical stress is introduced into a channel region of each of the n FET T1 and the p FET T2 within the semiconductor structure whose schematic cross-sectional diagram is illustrated in FIG. 11. Such a vertical mechanical stress is particularly desirable within an n FET when the vertical mechanical stress in a vertical compressive mechanical stress since such a vertical compressive mechanical stress within an n FET typically provides an enhanced electron charge carrier mobility within the n FET.

The preferred embodiments of the invention are illustrative of the invention rather than limiting of the invention. Revisions and modifications may be made to methods, materials, structures and dimensions of a semiconductor structure in accordance with the preferred embodiments, while still fabricating a semiconductor structure in accordance with a method of the invention, further in accordance with the accompanying claims.

1-20. (canceled)

21. A method for fabricating a field effect transistor comprising:
forming a gate electrode over a channel region that separates a plurality of source/drain regions within a semiconductor substrate;
forming a first metal-semiconductor layer having a first volume upon the gate electrode;
capping the first metal-semiconductor layer; and
processing the first metal-semiconductor layer to form a second metal-semiconductor layer that has a second volume different than the first volume, the difference in volume between the second volume and the first volume introducing a stress into the channel region, wherein the first metal-semiconductor layer comprises an osmium rich osmium silicide, and the second metal-semiconductor layer comprises a silicon rich osmium silicide, said second volume is greater than the first volume, and said stress is a vertical compressive stress.
